(19) United States
(12) Patent Application Publication
(10) Pub. No.: US 2014/0261676 A1
(43) Pub. Date: Sep. 18, 2014

(54) USE OF A BUFFER LAYER TO FORM BACK CONTACT TO A GROUP IIB-VIA COMPOUND DEVICE

(71) Applicant: Encoresolar, Inc., San Jose, CA (US)

(72) Inventor: Bulent M. BASOL, Manhattan Beach, CA (US)

(73) Assignee: ENCORESOLAR, INC., San Jose, CA (US)

(21) Appl. No.: 14/216,988

(22) Filed: Mar. 17, 2014

Related U.S. Application Data
(60) Provisional application No. 61/802,478, filed on Mar. 16, 2013.

(51) Int. Cl. H01L 31/0216; H01L 31/18

(52) U.S. Cl. CPC H01L 31/02167; H01L 31/1828
USPC 136/256; 438/95

(57) ABSTRACT

A method of making a back contact to a Group IIB-VIA compound layer employed in a device such as a solar cell and in particular a CdTe solar cell. The method involves deposition of a contact buffer layer comprising an ionic conductor over a surface of a CdTe film, which is the absorber of the solar cell. A highly conductive contact layer is deposited over the contact buffer layer. In some examples, the compound device is a device such as a solar cell and in particular a CdTe solar cell in a sub-strate configuration or structure. The method involves deposition of a contact buffer layer comprising an ionic conductor on a surface of a highly conductive contact layer. A CdTe film, which is the absorber layer of the solar cell is then deposited over the contact buffer layer.

### RELATED U.S. APPLICATION DATA

U.S. Provisional Application No. 61/802,478, filed electronically on Mar. 16, 2013, the disclosure of which is herein incorporated by reference in its entirety.

### FIELD OF THE INVENTION

The present invention relates to methods for making high quality back contacts to Group IIB-VIA compound solar cells, more specifically CdTe solar cells.

### BACKGROUND OF THE INVENTION

Solar cells and modules are photovoltaic (PV) devices that convert sunlight energy into electrical energy. The most common solar cell material is silicon (Si). However, lower cost PV cells may be fabricated using thin film growth techniques that can deposit solar-cell-quality polycrystalline compound absorber materials on large area substrates using low-cost methods. Group IIB-VIA compound semiconductors comprising some of the Group IIB (Zn, Cd, Hg) and Group VIA (O, S, Se, Te, Po) materials of the periodic table are excellent absorber materials for thin film solar cell structures. Especially CdTe has proved to be a material that can be used in manufacturing high efficiency solar panels at a manufacturing cost of below $0.8/W.

FIG. 1A shows a prior art structure of a CdTe based thin film solar cell. FIG. 1A shows a “super-strate” structure 10 or configuration, wherein light enters the active layers of the device through a transparent sheet 11. The transparent sheet 11 serves as the support on which the active layers are deposited. In fabricating the “super-strate” structure 10, a transparent conductive layer (TCL) 12 is first deposited on the transparent sheet 11. Then a junction partner layer 13 is deposited over the TCL 12. A CdTe absorber film 14, which is a near-intrinsic or p-type semiconductor film, is next formed on the junction partner layer 13. Then an ohmic contact layer 15 is deposited on the CdTe absorber film 14, completing the solar cell. As shown by arrows 18 in FIG. 1A, light enters this device through the transparent sheet 11. In the “super-state” structure 10 of FIG. 1A, the transparent sheet 11 may be glass or a material (e.g., a high temperature polymer such as polyimide) that has high optical transmission (such as higher than 80%) in the visible spectra of the sun light. The TCL 12 is usually a transparent conductive oxide (TCO) layer comprising any one of; tin-oxide, cadmium-tin-oxide, indium-tin-oxide, and zinc-oxide which are doped to increase their conductivity. There may also be a highly resistive oxide or sulfide window buffer layer at the surface of the TCL 12 facing the junction partner layer 13, to improve device efficiency. Such window buffer layers may comprise undoped tin-oxide, tin-zinc-oxide, tin-cadmium-oxide, etc. Multi layers of TCO materials as well as their alloys or mixtures may also be utilized in the TCL 12. The junction partner layer 13 is typically a CdS layer, but may alternately be another compound layer such as a layer of Cd—Zn—S, ZnS, ZnSe, Zn—S—Se, Cd—Zn—Se, etc. The ohmic contact 15 is typically comprises a highly conductive metal such as Mo, Ni, Cr, Ti, Al, a doped transparent conductive oxide such as the TCOs mentioned above, or graphite. The rectifying junction, which is the heart of this device, is located near an interface 19 between the CdTe absorber film 14 and the junction partner layer 13.

In the “sub-strate” structure 17 of FIG. 1B, the ohmic contact layer 15 is first deposited on a sheet substrate 16, and then the CdTe absorber film 14 is formed on the ohmic contact layer 15. This is followed by the deposition of the junction partner layer 13 and the transparent conductive layer (TCL) 12 over the CdTe absorber film 14. There may also be a highly resistive oxide or sulfide window buffer layer at the surface of the TCL 12 facing the junction partner layer 13, to improve device efficiency. As shown by arrows 18 in FIG. 1B, light enters this device through the TCL 12. There may also be finger patterns (not shown) on the TCL 12 to lower the series resistance of the solar cell. The sheet substrate 16 does not have to be transparent in this case. Therefore, the sheet substrate 16 may comprise a sheet or foil of metal, glass or polymeric material.

Ohmic contacts to near-intrinsic or p-type CdTe are difficult to make because of the high electron affinity of the material. Various approaches have been reported on the topic of making ohmic contacts to CdTe films. For example, U.S. Pat. No. 4,456,630 by Basol describes a method of forming ohmic contacts to a CdTe film comprising etching the film surface with an acidic solution, then etching with a strong basic solution and finally depositing a conductive metal. In U.S. Pat. No. 4,666,569 granted to Basol a multi layer ohmic contact is described where a very thin, only 0.5-5 nm thick, interlayer of copper is formed on an etched CdTe surface before a metallic contact is deposited. U.S. Pat. No. 4,735,662 describes a contact stack comprising 1-5 nm thick copper film, an isolation layer such as a carbon or graphite layer, and an electrically conducting layer such as an aluminum layer. U.S. Pat. No. 5,909,632 describes a method of improving ohmic contact to CdTe by depositing a first undoped layer of ZnTe, then a doped ZnTe layer, and finally depositing a metal layer. The doped ZnTe layer is doped by Cu at concentrations of about 6 atomic percent. U.S. Pat. No. 5,472,910 forms an ohmic contact by; i) depositing a viscous liquid layer containing a Group IB metal salt on the CdTe surface, ii) heating the layer to allow the dopant diffuse into the CdTe surface, iii) removing the dried layer from the CdTe surface, iv) cleaning the CdTe surface, and, v) depositing a conductive contact layer on the cleaned surface. U.S. Pat. No. 5,557,146 describes a CdTe device structure with an ohmic contact comprising a graphite paste containing mercury telluride and copper telluride.

As the brief review above demonstrates ohmic back contacts to CdTe have so far been processed by three different routes. In a first approach a highly conductive Cu containing layer, such as a layer of Cu, Cu-telluride, or Cu-doped graphite is formed on the CdTe surface. A metal contact layer may then be deposited over the highly conductive Cu containing layer if the thickness of the highly conductive Cu-containing layer would not be adequate for lateral conduction of the generated current. The whole material stack may then be heat treated. In a second approach employed to make an ohmic contact to CdTe, a Cu-containing layer, such as a layer of Cu, Cu-telluride, or Cu-chloride, may be deposited on the CdTe surface. This may then be followed by a heat treatment step to diffuse the Cu dopant into the CdTe absorber. The Cu-containing film is then removed from the surface of the CdTe layer, and a highly conducting metal contact layer is deposited on the doped CdTe surface to form the ohmic contact with high conduction in the plane of the contact layer. In a third approach, a doped semiconductor film such as a Cu-doped ZnTe layer is formed on the CdTe surface. A metal contact layer is then deposited over the Cu-doped ZnTe layer to provide an ohmic contact.

Unlike electronic conductors, such as metals, that conduct electricity through motion of electrons, a group of materials called ionic conductors conduct electrical current through the motion of ions. These materials usually have much lower electrical current conductivity than metals and their ionic conductivity increases with temperature unlike metals whose electronic conductivity decreases with increased temperature.

The present inventions provide methods of processing improved ohmic contacts to Group IIB-VIA compound thin films such as CdTe films, utilizing back contact buffer layers comprising ionic conductors. The present inventions also provide new device structures with improved ohmic contacts.

### BRIEF DESCRIPTION OF THE DRAWINGS

FIG. 1A is a cross-sectional view of a prior-art CdTe solar cell with a “super-strate structure”.

FIG. 1B is a cross-sectional view of a prior-art CdTe solar cell with a “substrate structure”.

FIG. 2A shows a CdTe solar cell structure fabricated in accordance with embodiments of the present inventions.

FIG. 2B shows a CdTe solar cell structure fabricated in accordance with embodiments of the present inventions.

### DETAILED DESCRIPTION OF THE INVENTION

FIG. 2A shows a device structure 20 formed in accordance with a first embodiment of the present inventions. FIG. 2B shows a device structure 30 formed in accordance with another embodiment of the present inventions. It should be noted that a back contact buffer layer 21 is inserted between the CdTe absorber film 14, and the ohmic contact layer 15 in the device structure 20 of FIG. 2A and the device structure 30 of FIG. 2B.

The back contact buffer layer 21 of FIG. 2A and FIG. 2B comprises an ionic conductor. Ionic conductors are materials that conduct electricity through ion migration via defects, such as Schottky defects and Frenkel defects in the material, which include atomic vacancies and interstitials. Ionic conductivity is generally between 0.0001-0.1 ohm⁻¹ cm⁻¹ and such materials are sometimes called solid electrolytes. If the ionic conductivity is more than 0.1 ohm⁻¹ cm⁻¹, the ionic conductor may be called fast ionic conductor or superionic conductor. Fast and super ionic conductors have very low electronic conductivity but relatively high ionic conductivity. Furthermore, their ionic conductivity is still much lower than the electronic conductivity of metals which are larger than 1000 ohm⁻¹ cm⁻¹. For example RbAg₄I₅ is considered to be an advanced superionic conductor since its ionic conductivity is larger than 0.25 ohm⁻¹ cm⁻¹ while its electronic conductivity is about 0.000000001 ohm⁻¹ cm⁻¹ at room temperature. Some materials, such as Li intercalated graphite and LiₓCoO₂, may have mixed (ionic and electronic) conductivities. For the purpose of this invention we call a material ionic conductor as long as it has appreciable, such as larger than 5%, preferably larger than 10%, and most preferably larger than 30% ionic conductivity.

The back contact buffer layer 21 may comprise at least one of a cationic ionic conductor and an anionic ionic conductor. The cationic ionic conductors include materials that conduct electricity through the motion of cations such as Li⁺, Na⁺, K⁺, Ag⁺, Cu⁺, Tl⁺, Pb²⁺, H⁺. Some examples of cationic ionic conductors that can be employed in the back contact buffer layer 21 include, but are not limited to, AgI, CuI, Rb—Ag—I compositions such as RbAg₄I₅, Cu—Rb—Cl—I compositions such as Cu₄RbCl₃I₂ and Rb₄Cu₁₆I₇Cl₁₃, sodium beta-alumina, Na₃Zr₂PSi₂O₁₂ (NASICON), and Li(Co, Ni, Mn)O₂. In the anionic ionic conductors the current carriers are F⁻ or O²⁻. Some examples of the anionic ionic conductors include, but are not limited to, Bi₂O₃, Defect Perovskites (such as Ba—In—O and La—Ca—Mn—O compositions), cubic stabilized zirconia (Y—Zr—O and Ca—Zr—O compositions), PbF₂ and (Ba, Sr, Ca)F₂.

The back contact buffer layer 21 comprises an ionic conductor. In an embodiment of the present inventions the ionic conductor in the contact buffer layer 21 preferably comprises iodine (I), and more preferably comprises both Cu and I. The back contact buffer layer 21 can be formed through various techniques including, but not limited to, vapor deposition such as chemical vapor deposition, thermal evaporation and physical vapor deposition, electrodeposition, electroless deposition such as chemical bath deposition or dip coating, various spraying approaches, doctor-blading, and nano particle ink deposition. The back contact buffer layer 21 may be treated after its deposition through techniques such as high temperature (>100° C.) annealing and laser irradiation. The thickness of the back contact buffer layer 21 may be in the range of 0.1 nm to 200 nm, preferably in the range of 0.5 nm to 100 nm and most preferably in the range of 0.5 nm to 50 nm. It should be noted that presence of a contact buffer layer 21 comprising an ionic conductor with relatively poor electronic conductivity but much higher ionic conductivity avoids the possible electrical shorts between the highly conductive ohmic contact layer 15 and the TCL 12 through pinholes or conductive pathways such as grain boundaries that may be present in the CdTe absorber film 14. Consequently, the quality and light conversion efficiency of the device improve. This helps fabrication of a device with very thin (less than or equal to 1.2 micrometer) Group IIB-VIA absorber layer. It has been published in the literature (K. J. Hsiao and J. R. Sites, Progress in Photovoltaics: Research and Applications, Vol: 20, Page: 486, 2012) that such thin devices with electron reflector at the back contact can potentially yield 20% efficiency. The contact buffer layers of the present inventions may at the same time act as electron reflectors or they may form good contacts to electron reflectors on CdTe layer surfaces. It should be noted that the contact buffer layer 21 of FIG. 2A and FIG. 2B do not have to be a continuous layer. It may have openings and pinholes. However, it is preferred that the contact buffer layer 21 has at least 20% coverage, preferably over 30% coverage and most preferably has over 50% coverage of the surface it is deposited on.

In a preferred embodiment, a CdTe solar cell with the device structure 20 depicted in FIG. 2A may be processed as follows. A transparent conductive layer (TCL) 12 may first be deposited on the transparent sheet 11. Then a junction partner layer 13 may be deposited over the TCL 12. A CdTe absorber film 14, which is a p-type semiconductor film, may next be formed on the junction partner layer 13. Then a back contact buffer layer 21 may be deposited over the CdTe absorber film 14. There may be an optional electron reflector interface film, such as a film material with a bandgap larger than CdTe, between the CdTe absorber film 14 and the contact buffer layer 21. An example of an electron reflector interface film comprises Zn. An ohmic contact layer 15 may then be deposited on the back contact buffer layer 21, completing the solar cell. There may be other processing steps employed during the completion of the solar cells. These steps may include, but may not be limited to, heat treatments, surface cleaning procedures and chemical etching processes. For example, high temperature heat treatment steps may be used before and/or after the deposition of the back contact buffer layer 21 to improve the quality of the CdTe absorber film 14 and/or the back contact buffer layer 21. The temperature range for such heat treatments may be 100-600° C., preferably 150-500° C. There may also be chemical etching and/or surface cleaning steps applied to the exposed surface of the CdTe absorber film 14 before the deposition of the contact buffer layer 21, and/or to the exposed surface of the contact buffer layer 21 before the deposition of the ohmic contact layer 15. Chemical etching and surface cleaning steps may employ chemicals such as water, inorganic acidic solutions, inorganic basic solutions and organic solutions comprising agents such as dimethylsulfoxide, dimethyl formimide and ethylenediamine. The surface cleaning and chemical etching steps may be carried out at room temperature or at an elevated temperature in a range of 25-100° C.

In another preferred embodiment, a CdTe solar cell with the device structure 30 depicted in FIG. 2B may be processed as follows. An ohmic contact layer 15 may first be deposited on a sheet substrate 16. A back contact buffer layer 21 may then be deposited on the ohmic contact layer 15. A CdTe absorber film 14 may be formed on the back contact buffer layer 21. This may be followed by the deposition of a junction partner layer 13 and a transparent conductive layer (TCL) 12 over the CdTe absorber film 14. There may be other processing steps employed during the completion of the solar cells. These steps may include, but may not be limited to, heat treatments, surface cleaning procedures and chemical etching processes. For example, high temperature heat treatment steps may be used after the deposition of the back contact buffer layer 21 or after the deposition of the CdTe absorber film 14 to improve the quality of the back contact buffer layer 21 and/or the CdTe absorber film 14. The temperature range for such heat treatments may be 100-600° C., preferably 150-500° C. There may also be chemical etching and/or surface cleaning steps applied to the exposed surface of the ohmic contact layer 15 before the deposition of the contact buffer layer 21, and/or to the exposed surface of the contact buffer layer 21 before the deposition of the CdTe absorber film 14. Chemical etching and surface cleaning steps may employ chemicals such as water, inorganic acidic solutions, inorganic basic solutions and organic solutions comprising agents such as dimethylsulfoxide, dimethyl formimide and ethylenediamine. The surface cleaning and chemical etching steps may be carried out at room temperature or at an elevated temperature in a range of 25-100° C.

Embodiments of the invention have been described using CdTe as an example. Methods and structures described herein may also be used to form ohmic contacts to other Group IIB-VIA compound films such as ZnTe and other materials that may be described by the formula Cd(Mn, Mg, Zn)Te. The family of compounds described by Cd(Mn, Mg, Zn)Te includes materials which have Cd and Te and additionally at least one of Mn, Mg and Zn in their composition. It should be noted that adding Zn, Mn or Mg to CdTe increases its bandgap from 1.47 eV to a higher value.

Although the present invention is described with respect to certain preferred embodiments, modifications thereto will be apparent to those skilled in the art.

What is claimed:

1. A device structure comprising;
a Group IIB-VIA compound film;
a contact layer; and
a back contact buffer layer disposed between the Group IIB-VIA compound film and the contact layer, wherein the back contact buffer layer comprises an ionic conductor.

2. The structure in claim 1, wherein a thickness of the back contact buffer layer is in the range of 0.1-50 nm.

3. The structure in claim 1, wherein the device is a solar cell and the Group IIB-VIA compound film comprises CdTe.

4. The structure in claim 3, wherein the ionic conductor comprises at least one of Li intercalated graphite, LiₓCoO₂, sodium beta-alumina, Na₃Zr₂PSi₂O₁₂, Li(Co, Ni, Mn)O₂, and iodine (I).

5. The structure in claim 4, wherein the ionic conductor comprises iodine (I) and copper (Cu).

6. The structure in claim 5, wherein the ionic conductor comprises at least one of CuI and Cu—Rb—Cl—I compositions.

7. The structure in claim 3, wherein an electron reflector material film is disposed between the CdTe compound film and the back contact buffer layer.

8. The structure in claim 3, wherein the ionic conductor comprises an anionic ionic conductor.

9. The structure in claim 7, wherein the ionic conductor comprises an anionic ionic conductor.

10. A method of fabricating a device comprising;
forming a Group IIB-VIA compound film;
forming a contact layer; and
disposing a back contact buffer layer between the Group IIB-VIA compound film and the contact layer, wherein the back contact buffer layer comprises an ionic conductor.

11. The method in claim 10, wherein a thickness of the back contact buffer layer is in the range of 0.1-50 nm.

12. The method in claim 10, wherein the Group IIB-VIA compound film comprises CdTe.

13. The method in claim 12, wherein the ionic conductor comprises at least one of Li intercalated graphite, LiₓCoO₂, sodium beta-alumina, Na₃Zr₂PSi₂O₁₂, Li(Co, Ni, Mn)O₂, and iodine (I).

14. The method in claim 13, wherein the ionic conductor comprises iodine (I) and copper (Cu).

15. The method in claim 14, wherein the ionic conductor comprises at least one of CuI and Cu—Rb—Cl—I compositions.

16. The method in claim 12, wherein an electron reflector material film is disposed between the CdTe compound film and the back contact buffer layer.

17. The method in claim 12, wherein the ionic conductor comprises an anionic ionic conductor.

18. The method in claim 15, wherein the ionic conductor comprises an anionic ionic conductor.

19. The method in claim 10, further comprising annealing after disposing the back contact buffer layer.

20. The method in claim 19, wherein the annealing is carried out at a temperature range of 150-500° C.
